(19) United States
(12) Patent Application Publication
(10) Pub. No.: US 2014/0348282 A1
(43) Pub. Date: Nov. 27, 2014

(54) OSCILLATION DEVICE AND COMMUNICATION SYSTEM

(71) Applicant: NIHON DEMPA KOGYO CO., LTD., Tokyo (JP)

(72) Inventor: SHOICHI TSUCHIYA, SAITAMA (JP)

(73) Assignee: NIHON DEMPA KOGYO CO., LTD., Tokyo (JP)

(21) Appl. No.: 14/281,857

(22) Filed: May 19, 2014

(30) Foreign Application Priority Data
May 21, 2013 (JP) 2013-107179

(51) Int. Cl. H03L 7/00; H04L 7/033

(52) U.S. Cl. CPC H03L 7/00; H04L 7/0331
USPC 375/376; 331/34

(57) ABSTRACT

An oscillation device includes a voltage control oscillation unit, a dividing unit, an output phase comparison unit, and a control voltage supply unit. The voltage control oscillation unit is configured to oscillate an oscillation frequency signal with a frequency f1 according to a control voltage. The dividing unit is configured to divide the frequency of the oscillation frequency signal into 1/N (N is a natural number) to match with a frequency f2 of a reference frequency signal input from outside. The output phase comparison unit is configured to compare a phase of the divided oscillation frequency signal with a phase of the reference frequency signal and output a signal according to a phase difference. The control voltage supply unit is configured to generate a control voltage according to the signal according to the phase difference and supply the control voltage to the voltage control oscillation unit.

### CROSS-REFERENCE TO RELATED APPLICATION

This application claims the priority benefit of Japanese application serial no. 2013-107179, filed on May 21, 2013. The entirety of the above-mentioned patent application is hereby incorporated by reference herein and made a part of this specification.

### BACKGROUND

1. Technical Field

This disclosure relates to an art of adjusting a phase of a frequency signal that is output from an oscillation device including a phase locked loop (PLL) circuit.

2. Description of the Related Art

A frequency synthesizer provided at a station for mobile communication or terrestrial digital broadcasting is equipped with an oscillation device including a PLL circuit for external synchronization. Such a PLL circuit for external synchronization outputs a frequency signal with a frequency matched with a frequency of a reference frequency signal, which is obtained externally, to a digital PLL, which includes a voltage-controlled crystal oscillator (VCXO), positioned at a latter part.

A frequency signal oscillated in a reference oscillator, such as a cesium frequency standard oscillator and a rubidium frequency standard oscillator, is divided and provided as a reference frequency signal. Inputs of such a reference frequency signal may temporarily be interrupted for example when a failure occurs in the aforementioned device or its transmitting path. Also for maintenance or other servicing on a frequency synthesizer, the synthesizer power is turned off and on again.

The inventors compared frequency signals output from a PLL circuit at before and after a restoration of such an interrupted reference frequency signal or a power on. Consequently, the inventors have found that phases may deviate or fluctuate among frequency signals at a restoration of such an interrupted reference frequency signal or a power off and on, even if the PLL circuit is locked to match a frequency of an output frequency signal with a frequency of a reference frequency signal.

A frequency signal output from this type of PLL circuit is sometimes used as an external synchronization signal for another device in the same system. If a phase of a frequency output from the PLL circuit deviates as described above while the another device in the system is operating in a condition where its phase relation is always required to be constant with the original reference frequency signal, a clock inside the device may deviate causing a deviated operation timing, and consequently an error.

Paragraphs 0002 to 0005 and FIG. 6 of Japanese Unexamined Patent Application Publication No. 2004-120443 (hereinafter referred to as Patent Literature 1) discloses a PLL circuit that generates an internal clock signal. The internal clock signal is synchronized with an externally obtained clock signal with a certain level of phase difference in order for the PLL circuit to provide the internal clock signal to a plurality of function blocks in a semiconductor integrated circuit. The PLL circuit adds a phase difference to an external clock signal at a delay circuit, then divides and multiplies the external clock signal at a divider and a multiplier. The divided and multiplied external clock signal is then output as an internal clock signal. Patent Literature 1, however, does not disclose an external clock interruption or stableness of internal clock phases at before and after an interruption of an external clock signal and a power on.

The present disclosure has been made under these circumstances, and it is an object of this disclosure to provide an oscillation device that can output a frequency signal with a frequency and phase matched with a frequency and phase of an external reference signal.

### SUMMARY

An oscillation device according to the disclosure includes a voltage control oscillation unit, a dividing unit, an output phase comparison unit, and a control voltage supply unit. The voltage control oscillation unit is configured to oscillate an oscillation frequency signal with a frequency f1 according to a control voltage. The dividing unit is configured to divide the frequency of the oscillation frequency signal into 1/N (N is a natural number) to match with a frequency f2 of a reference frequency signal input from outside. The output phase comparison unit is configured to compare a phase of the divided oscillation frequency signal with a phase of the reference frequency signal and output a signal according to a phase difference. The control voltage supply unit is configured to generate a control voltage according to the signal according to the phase difference and supply the control voltage to the voltage control oscillation unit. Thee oscillation device is configured to output the divided oscillation frequency signal to outside. Here, N of the dividing unit is a natural number equal to or more than two, or N of the dividing unit is one.

The oscillation device may include the following features. (a) The voltage control oscillation unit is an oven controlled crystal oscillator. (b) When an input of the reference frequency signal is interrupted, the oscillation device is configured to fix a control voltage supplied to the voltage control oscillation unit at a control voltage when the reference frequency signal is interrupted and continue the output of the oscillation frequency signal to outside.

Further, a communication system includes the above-described oscillation device and a device configured to use the divided oscillation frequency signal output from the oscillation device as an external synchronization signal.

In this disclosure, a PLL circuit is used to divide an oscillation frequency signal with a frequency f1, which is oscillated at a voltage control oscillation unit, into 1/N at the a dividing unit such that the phase of the divided oscillation frequency signal matches with a phase of a reference frequency signal with a frequency f2 to be compared with the divided oscillation frequency signal. The divided oscillation frequency signal is then output to the outside. As a result, the frequency and phase relation becomes constant among the reference frequency signal, the frequency signal for phase comparison, and the frequency signal for external output, thus ensuring stable frequency signal outputs.

### BRIEF DESCRIPTION OF THE DRAWINGS

FIG. 1 is a block diagram illustrating a conventional PLL circuit for external synchronization.

FIG. 2 is an explanatory drawing illustrating a phase relation between a reference frequency signal and an output frequency signal in the aforementioned conventional PLL circuit.

FIG. 3 is a block diagram illustrating a PLL circuit according to an embodiment of this disclosure.

FIG. 4 is an explanatory drawing illustrating a phase relation between a divided oscillation frequency signal and a reference frequency signal at the PLL circuit according to the embodiment.

FIG. 5 is a block diagram illustrating a PLL circuit according to another embodiment of this disclosure.

FIG. 6 is a block diagram illustrating a PLL circuit according to a comparative example.

FIG. 7 is an explanatory drawing illustrating a mechanism of phase deviation occurrence among frequency signals in the PLL circuit according to the comparative example.

### DETAILED DESCRIPTION

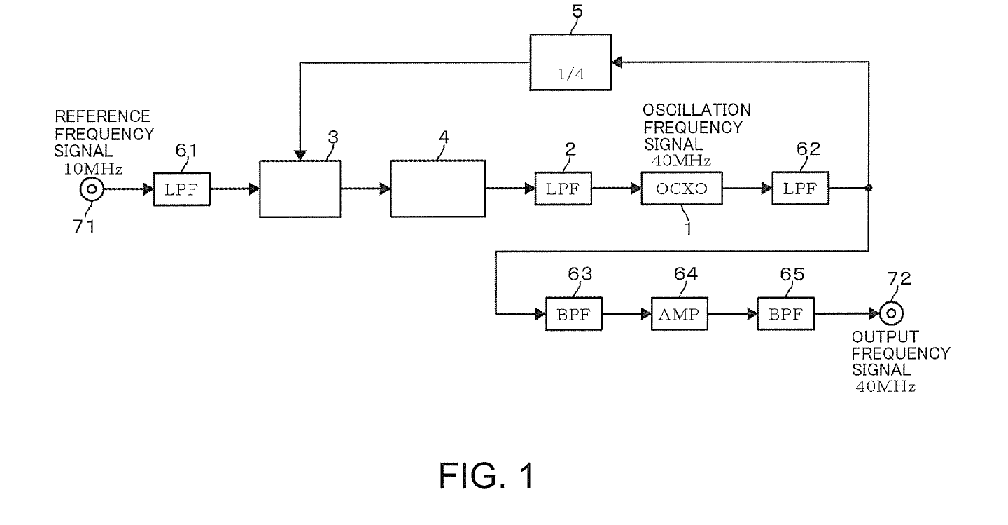

First of all, to illustrate features of this disclosure, a conventional PLL circuit for external synchronization is described. In the PLL circuit illustrated in a block diagram of FIG. 1, an oven controlled crystal oscillator 1 (OCXO), which functions as a voltage control oscillation unit, oscillates an oscillation frequency signal (frequency f1=40 MHz) with a rectangular wave. The oscillation frequency signal is then divided into 1/4 (division ratio N=4) at a divider 5 (dividing unit). Subsequently, a phase comparator 3 (phase comparison unit) compares a phase of the divided oscillation frequency signal with a phase of a rectangular-wave reference frequency signal (frequency f2=10 MHz), which is input from outside. Here, reference numeral 71 in FIG. 1 denotes an input terminal for such a reference frequency signal, reference numeral 61 denotes a low-pass filter (LPF), which eliminates high frequency components within the reference frequency signal.

The phase comparator 3 outputs a signal according to a phase difference between the oscillation frequency signal and the reference frequency signal. The output signal from the phase comparator 3 is then boosted at a charge pump 4 and is fed to an LPF 2, which constitutes a loop filter. The LPF 2 converts the signal according to the phase difference into a DC voltage and supplies it as a frequency control voltage to an OCXO 1. Thus, the LPF 2 functions as a control voltage supply unit in this embodiment.

The OCXO 1 uses an oven to stabilize a temperature around a crystal resonator, which generates oscillation frequency signals, and reduces the effect of peripheral temperature changes on the oscillation frequency. Thus, the OCXO 1 is able to generate an oscillation frequency signal with a highly accurate and stable frequency. Furthermore, a comparison result obtained against the reference frequency signal at the phase comparator 3 is fed back as a control voltage. This feedback allows adjusting the frequency and phase in high accuracy.

Thus, the oscillation frequency signal with the adjusted frequency and phase has its high frequency components removed at an LPF 62 and is amplified at an amplifier 64. Then, the signal is extracted in a desired frequency range at band-pass filters (BPF) 63 and 65, and the signal is output from an output terminal 72 to a digital PLL at a latter part. Hereinafter, the frequency signal output from the output terminal 72 may be referred to as an output frequency signal.

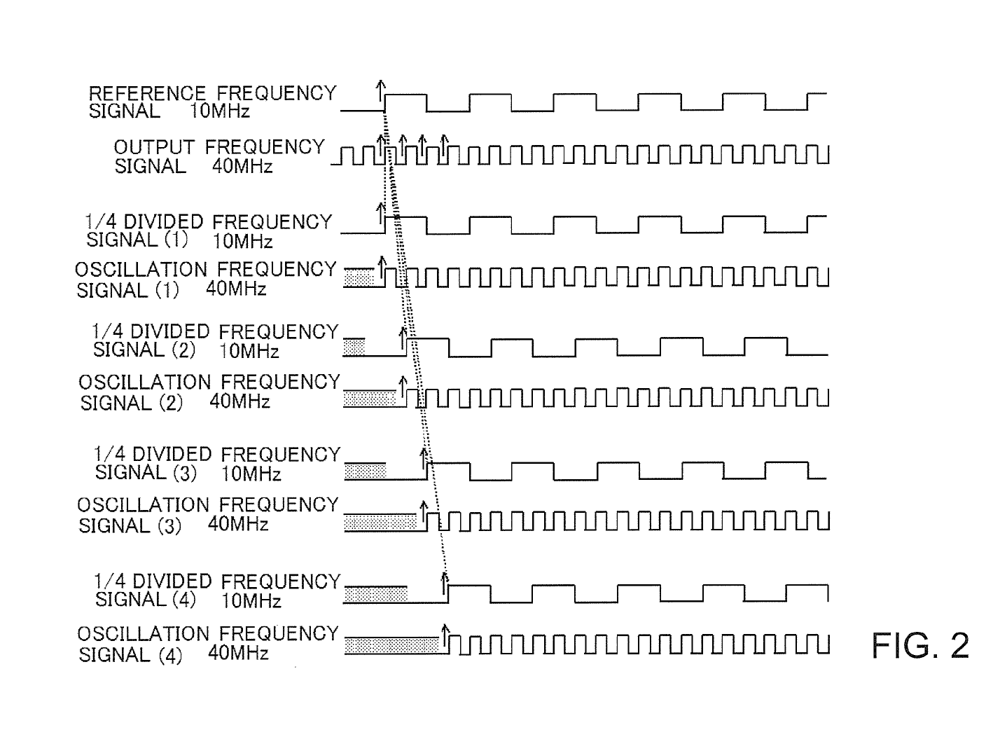

For example, with a restoration of an interrupted reference frequency signal or a power off and on, the frequency and the phase are adjusted between the reference frequency signal and the oscillation frequency signal divided at the divider 5 in the PLL circuit illustrated in FIG. 1. As illustrated in FIG. 2, the reference frequency signal has a frequency of 10 MHz, the OCXO 1 generates an oscillation frequency signal of approximately 40 MHz, the oscillation frequency signal is divided into 1/4 at the divider 5, and then the phase of the divided oscillation frequency and the phase of the reference frequency are compared. If the frequency and the phase match between the divided frequency signal (indicated with dotted lines in FIG. 2) and the reference frequency signal in that comparison result, the PLL circuit is locked (see (1) of FIG. 2 for an example).

The relation between the reference frequency signal and the output frequency signal in the above-described example is described. As illustrated with a waveform on a line 1 in FIG. 2, a reference frequency signal of 10 MHz is input from outside. On the other hand, the OCXO 1 in the PLL circuit generates a frequency signal of 40 MHz (sec the waveforms (1) to (4) on lines 4, 6, 8, and 10).

For example, a rectangular wave, which rises at a timing pointed with an arrow on a waveform diagram of the oscillation frequency signal (1) on a line 4, is divided at the divider 5 to obtain a 1/4 divided frequency signal (1) of 10 MHz. In the phase comparator 3, phases are compared between the 1/4 divided frequency signal (1) and the reference frequency signal (indicated with dotted lines). Then, a frequency signal with 40 MHz, where the phase of the 1/4 divided frequency signal (1) matches with the phase of the reference frequency signal, is output from the output terminal 72.

When dividing an oscillation frequency signal of 40 MHz, oscillation frequency signals (2) to (4), which have one to three phase cycles deviated from the phase of the oscillation frequency signal (1), may be divided to obtain 1/4 divided frequency signals (2) to (4). Even in this case, if the phases of the 1/4 divided frequency signals (2) to (4) match with the phase of the reference frequency signal, the phases of the output frequency signals match with each other.

Thus, assume that regardless of the dividing timing, the PLL circuit enables an output of the output frequency signal that has a constant phase relation with the reference frequency signal. Compared with this assumed PLL circuit, phases of the output frequency may deviate for example, when an oscillation frequency signal of 40 MHz is divided into 1/4 to output a frequency signal of 10 MHz (see the comparative example described later).

The PLL circuit provided in the oscillation device according to this embodiment is designed in consideration of such a problem.

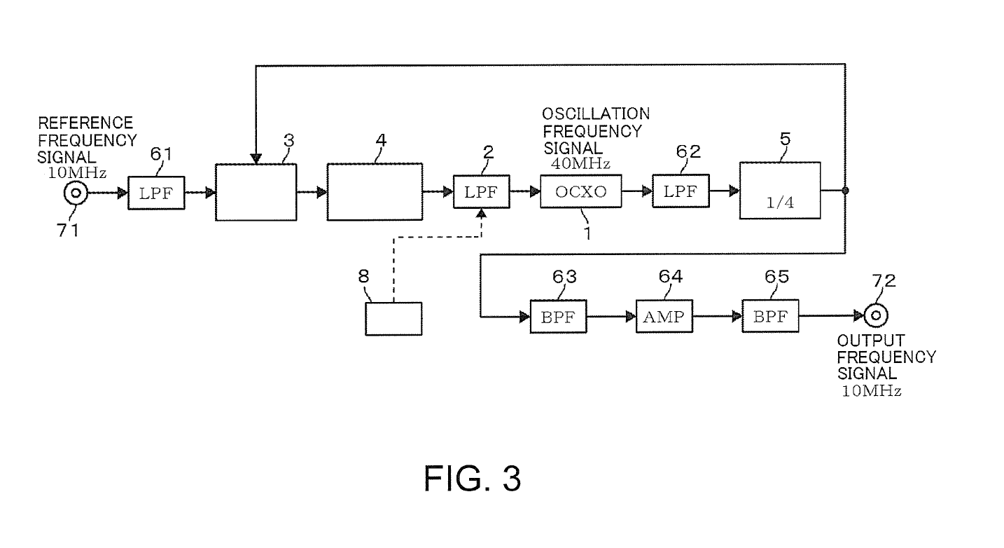

FIG. 3 is a block diagram illustrating the PLL circuit (indicated as EMBODIMENT 1) for external synchronization according to the embodiment of this disclosure. Hereinafter, in each block diagram illustrating the PLL circuit, like reference numerals same as in FIG. 1 designate identical configuration elements of the aforementioned conventional PLL circuit.

In the PLL circuit according to this embodiment is different from the conventional PLL circuit in the points below. In the PLL circuit according to this embodiment, a frequency signal of 40 MHz generated in the OCXO 1 is divided into 1/4 (division ratio N=4) at the divider 5, and the divided oscillation frequency signal branches to a phase comparison loop side for the phase comparator 3, and to an output side for the output terminal 72. In the conventional PLL circuit, an oscillation frequency signal branches to a frequency signal for phase comparison and a frequency signal for output, then the frequency signal for phase comparison is divided at the divider 5, which is provided in the phase comparison loop.

By employing a configuration illustrated in FIG. 3, the frequency (10 MHz according to this embodiment) and the phase match between the frequency signal for phase comparison, which is input to the phase comparator 3, and the frequency signal, which is output from the output terminal 72, in the PLL circuit. Thus, without depending on the dividing start timing of the divider 5, the frequency signals, whose phases are mutually matched, are output to the phase comparator 3 and to the output terminal 72.

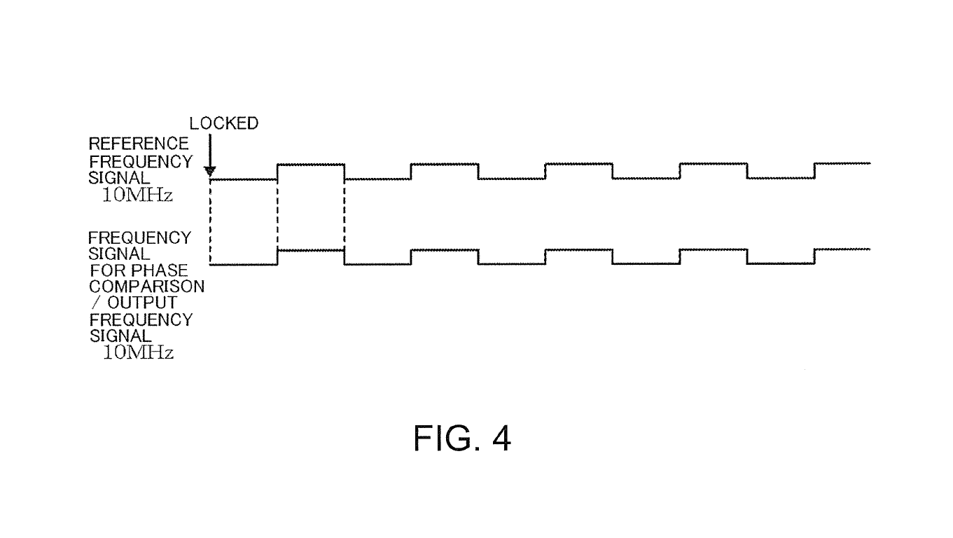

Furthermore, the phase of the reference frequency signal is stable before and after a restoration of an interrupted reference frequency signal or a power off and on of a frequency synthesizer. Thus, locking the PLL circuit allows outputs of phase-matched frequency signals at before and after such an event (FIG. 4).

Additionally, an oscillation device, where the PLL circuit according to this embodiment is provided, includes a controller 8. When an input of the reference frequency signal from outside is interrupted, the controller 8 controls a DC voltage (control voltage) to be fixed at a voltage when interrupted and continues oscillation by the OCXO 1. The DC voltage is a control voltage supplied from the LPF 2 to the OCXO 1. Consequently, a frequency signal with the oscillation frequency immediately before the reference frequency signal interruption is continuously output. The DC power supply to the OCXO 1 during an interruption of the reference frequency signal may be configured by providing an alternate power source other than the LPF 2. The voltage of the DC power, which is normally output from the LPF 2, may be output from this alternate power source to the OCXO 1 during an interruption of the reference frequency signal.

The PLL circuit provided at the oscillation device according to this embodiment provides the effects below. The oscillation frequency signal with frequency f1 oscillated at the OCXO 1 is divided in 1/N at the divider 5, the frequency of the divided frequency signal is then adjusted to match the frequency f2 of the reference frequency signal, which is to be compared with the frequency of the divided frequency signal, and the divided oscillation frequency signal is then output to the outside. As a result, the frequency and phase relation is constant among the reference frequency signal, the frequency signal for phase comparison, and the frequency signal for the output terminal 72. Thus, stable frequency signals are output without having a phase fluctuation caused by timing deviations, which are caused by the deviated dividing start timing at the divider 5.

Additionally, the frequency signal output from the PLL circuit is known to have a constant phase relation with the reference frequency signal. If the input of the reference frequency signal is interrupted, it is possible to have the DC voltage supplied from the LPF 2 to the OCXO 1 to be fixed at a certain voltage, divide the oscillation frequency signal output from the OCXO 1 into 1/4, and output a frequency signal of 10 MHz. The oscillation device including the exemplary PLL circuit, together with a device that uses the output frequency signal output from the oscillation device as an external synchronization signal, constitute a communication system. Additionally, the use of this output frequency signal as an external synchronization signal for a device at the latter part allows the reference frequency signal to be continuously input to such a device at the latter part, which requires a constant phase relation with the external synchronization signal, for a while until the reference frequency signal is restored.

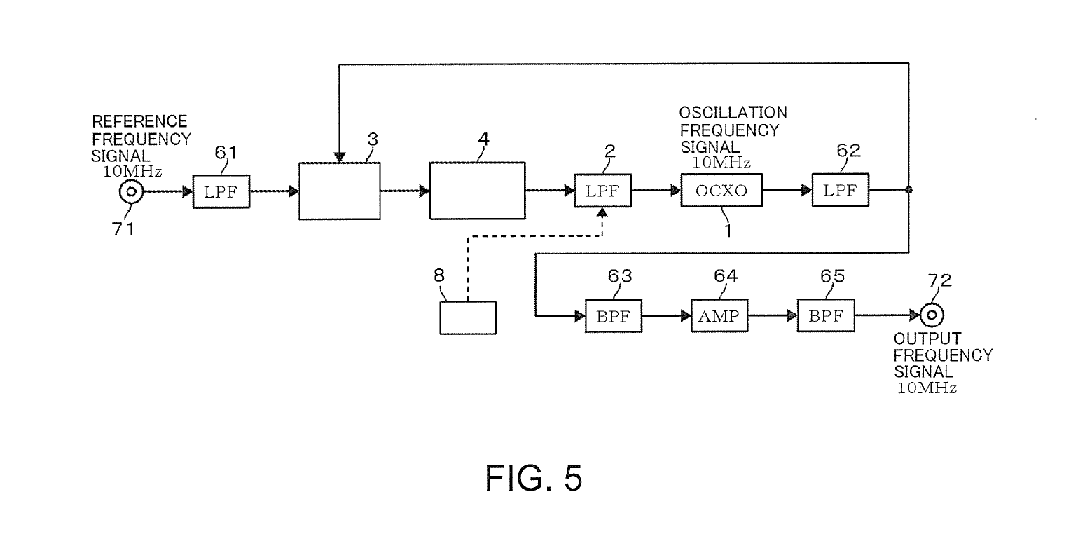

FIG. 5 illustrates an exemplary configuration of the PLL circuit according to another embodiment (indicated as EMBODIMENT 2 in FIG. 5). The exemplary PLL circuit is different from the PLL circuit illustrated in FIG. 3 in the points below. The frequency of the frequency signal oscillated at the OCXO 1 is 10 MHz, and the oscillation frequency signal oscillated at the OCXO 1 branches to the phase comparison loop and to the output side to the output terminal 72 without being divided at the OCXO 1.

In this configuration, as illustrated in FIG. 4, the frequency and the phase are mutually matched among the reference frequency signal, the frequency signal for phase comparison, and the frequency signal to be output from the output terminal 72. Thus, frequency signals with stable phases are output at before and after an event such as an interruption of the reference frequency signal and its restoration. Here, the PLL circuit illustrated in FIG. 5 is understood to have a divider that divides the oscillation frequency signal into 1/1 (division ratio N=1) in a latter part of the OCXO 1.

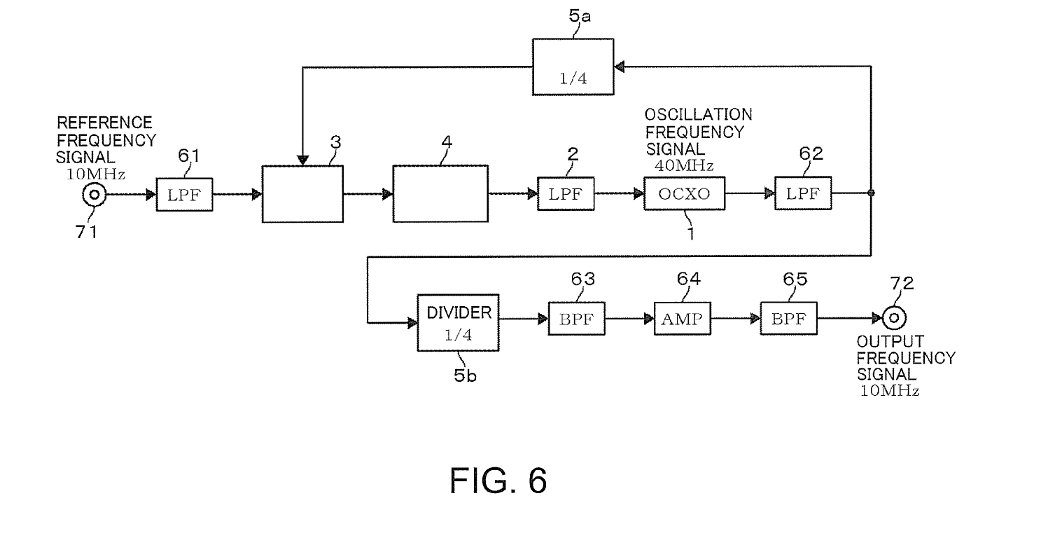

The PLL circuit in FIG. 6 is a comparative example where even if the frequency of the reference frequency signal matches with the frequency of the frequency signal output from the PLL circuit, the phase may be unstable at before and after an event such as an interruption of the reference frequency signal and its restoration. The PLL circuit according to the comparative example differs with the PLL circuit according to the embodiment (FIG. 3) in the points below. In the PLL circuit according to the comparative circuit, individual dividers 5a and 5b are respectively provided at the phase comparison loop and at the output side for the output terminal 72, at a latter part of the OCXO 1. In the PLL circuit according to the embodiment (FIG. 3), the frequency signal that is divided at the common divider 5 branches to the phase comparison loop and to the output terminal 72.

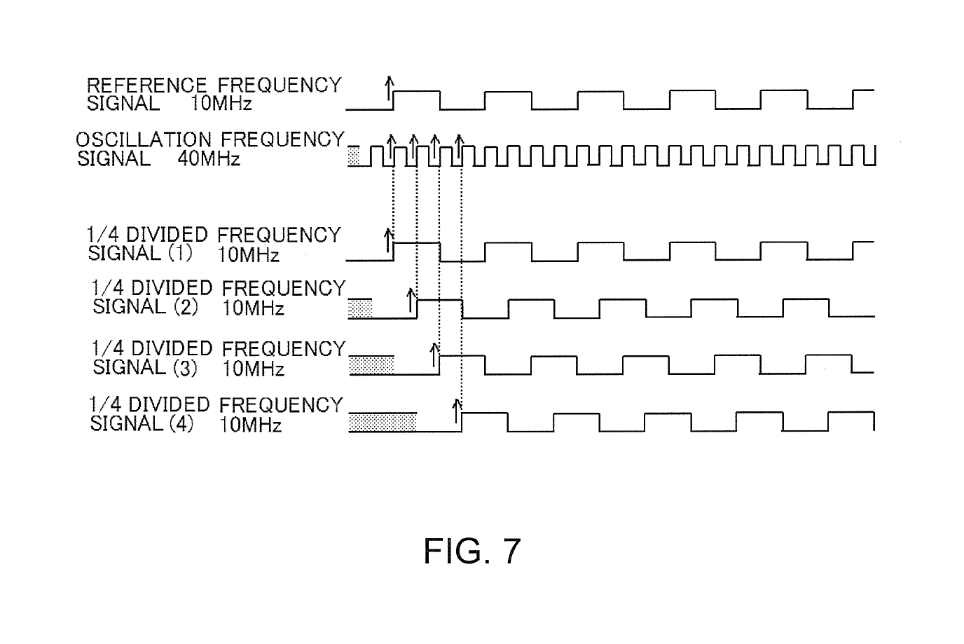

In the comparative example, dividing may start at two different timings of the two dividers 5a and 5b. Thus, the phase deviation may occur between the reference frequency signal and the output frequency signal. For example, assuming that the phases of the reference frequency signal and oscillation frequency signal are matched and the PLL circuit is locked, two cases below are considered. One case is when the dividing start timing at the divider 5a for the frequency signal for the phase comparison loop (see the 1/4 divided frequency signal (1) in FIG. 7) matches with the dividing start timing at the divider 5b for the frequency signal for the output side. The other case is when the dividing start timing at the divider 5b is delayed by units of one cycle (reference of 40 MHz).

In the latter case, as illustrated by the 1/4 divided frequency signals (1) to (4) in FIG. 7, four types of output frequency signals with deviated phases may be output. Thus, the probability where the reference frequency signal and the output frequency signal phase match decreases to 25%. This similarity applies to a case where the dividing start timing at the divider 5b for the output side is advanced by units of one cycle compared with the dividing start timing at the divider 5a in the phase comparison loop. In summary, a total of four output frequency signal types may be output in the phase relation with the reference frequency signal (see the 1/4 divided frequency signals (1) to (4) in FIG. 7).

According to the embodiments illustrated in FIGS. 3 and 5 as well as the conventional and comparative examples illustrated in FIGS. 1 and 6, it is understood that the following two points are required to obtain a frequency signal with a stable phase at before and after a restoration of the reference frequency signal or a power off and on: The frequency of the frequency signal at the phase comparison loop must be matched with the frequency of the reference frequency signal; and the output from the divider 5 (including when not providing the divider 5 with the division ratio N=1), which divides the frequency signal for the phase comparison, must be used as the output frequency signal.

In the embodiments described above, the voltage control oscillation unit provided in the PLL circuit is not limited to the OCXO 1, a temperature-compensated crystal oscillator (TCXO) or VCXO may be employed. Also, the reference frequency signal, which is obtained externally, may be divided in a divider and then input to the phase comparator 3. In such a case, as illustrated in FIG. 3, the output from the common divider 5 may be used to generate the frequency signal for the phase comparison as well as the output frequency signal (including a case without using the divider in FIG. 5 (division ratio N=1)), and to output the frequency signal with the phase matched with the reference frequency.

What is claimed is:

1. An oscillation device, comprising:
a voltage control oscillation unit, configured to oscillate an oscillation frequency signal with a frequency f1 according to a control voltage;
a dividing unit, configured to divide the frequency of the oscillation frequency signal into 1/N to match with a frequency f2 of a reference frequency signal input from outside, wherein N is a natural number;
a phase comparison unit, configured to compare a phase of the divided oscillation frequency signal with a phase of the reference frequency signal and output a signal according to a phase difference; and
a control voltage supply unit, configured to generate a control voltage according to the signal according to the phase difference and supply the control voltage to the voltage control oscillation unit, wherein
the oscillation device is configured to output the divided oscillation frequency signal to outside.

2. The oscillation device according to claim 1, wherein
N of the dividing unit is a natural number equal to or more than two.

3. The oscillation device according to claim 1, wherein
N of the dividing unit is one.

4. The oscillation device according to claim 1, wherein
the voltage control oscillation unit is an oven controlled crystal oscillator.

5. The oscillation device according to claim 1, wherein
when an input of the reference frequency signal is interrupted, the oscillation device is configured to fix a control voltage supplied to the voltage control oscillation unit at a control voltage when the reference frequency signal is interrupted and continue the output of the oscillation frequency signal to outside.

6. A communication system, comprising:
the oscillation device according to claim 1; and
a device, configured to use the divided oscillation frequency signal output from the oscillation device as an external synchronization signal.
